(19) United States
(12) Patent Application Publication
(10) Pub. No.: US 2009/0294971 A1
(43) Pub. Date: Dec. 3, 2009

(54) ELECTROLESS NICKEL LEVELING OF LGA PAD SITES FOR HIGH PERFORMANCE ORGANIC LGA

(75) Inventors: Edmund D. BLACKSHEAR, Wappingers Falls, NY (US); David J. RUSSELL, Owego, NY (US); Kevin A. DORE, Wappingers Falls, NY (US)

Correspondence Address: FREDERICK W. GIBB, III;Gibb Intellectual Property Law Firm, LLC, 2568-A RIVA ROAD, SUITE 304, ANNAPOLIS, MD, 21401, US

(73) Assignee: INTERNATIONAL BUSINESS MACHINES CORPORATION, Armonk, NY (US)

(21) Appl. No.: 12/131,298

(22) Filed: Jun. 2, 2008

(51) Int. Cl. H01L 23/488; H01L 21/44

(52) U.S. Cl. 257/762; 438/612; 257/E23.023; 257/E21.476

(57) ABSTRACT

A structure comprises: a substrate; at least one conductor on the substrate; at least one contact pad on the substrate; a mask over the conductor (wherein the mask comprises an opening over the contact pad and wherein the mask comprises a bottom surface contacting the substrate and a top surface opposite the bottom surface); and a contact pad plating layer on the contact pad and within the opening of the mask. The contact pad plating layer comprises a bottom surface contacting the contact pad and a top surface opposite the bottom surface, and the top surface of the contact pad plating layer is coplanar with the top surface of the mask.

### BACKGROUND

1. Field of the Invention

The embodiments of the invention generally relate to land grid array structure connections within flip chips, and, more particularly, to a contact pad plating layer within such connections.

2. Description of the Related Art

Conventional systems use land grid array (LGA) structures to connect substrates together. For example, it is known to form a laminated structure using flip chip technology. However, such technologies raise concerns regarding the ability to form high speed reliable connections. The embodiments discussed below address such issues.

### SUMMARY

In summary, an embodiment of the invention provides a structure comprising: a substrate; at least one conductor on the substrate; at least one contact pad on the substrate; a mask over the conductor (wherein the mask comprises an opening over the contact pad and wherein the mask comprises a bottom surface contacting the substrate and a top surface opposite the bottom surface); and a contact pad plating layer on the contact pad and within the opening of the mask. The contact pad plating layer comprises a bottom surface contacting the substrate and a top surface opposite the bottom surface, and the top surface of the contact pad plating layer is coplanar with the top surface of the mask.

In summary, a flip chip structure comprising: a laminated organic substrate; at least one wiring conductor on said substrate; at least one land grid array (LGA) contact pad on said substrate; a solder mask over said wiring conductor, wherein said solder mask comprises an opening over said LGA contact pad, and wherein said solder mask comprises a bottom surface contacting said substrate and a top surface opposite said bottom surface; and a contact pad plating layer on said LGA contact pad and within said opening of said solder ask, wherein said contact pad plating layer comprises a bottom surface contacting said substrate and a top surface opposite said bottom surface, and wherein said top surface of said contact pad plating layer is coplanar with said top surface of said mask.

In addition, a method embodiment herein comprises: patterning at least one conductor on a substrate; patterning at least one contact pad on the substrate; patterning a mask over the conductors (such that the mask comprises an opening over the contact pad and such that the mask comprises a bottom surface contacting the substrate and a top surface opposite the bottom surface); and forming a contact pad plating layer on the contact pad and within the opening of the mask (such that the contact pad plating layer comprises a bottom surface contacting the contact pad and a top surface opposite the bottom surface, and such that the top surface of the contact pad plating layer is coplanar with the top surface of the mask).

These and other aspects of the embodiments of the invention will be better appreciated and understood when considered in conjunction with the following description and the accompanying drawings. It should be understood, however, that the following descriptions, while indicating embodiments of the invention and numerous specific details thereof, are given by way of illustration and not of limitation. Many changes and modifications may be made within the scope of the embodiments of the invention without departing from the spirit thereof, and the embodiments of the invention include all such modifications.

### BRIEF DESCRIPTION OF THE DRAWINGS

The embodiments of the invention will be better understood from the following detailed description with reference to the drawings, in which:

FIG. 1 is a schematic cross-sectional diagram of a connection section of a flip chip module;

FIG. 2 is a schematic cross-sectional diagram of a connection section of a flip chip module;

FIG. 3 is a schematic cross-sectional diagram of a connection section of a flip chip module;

FIG. 4 is a schematic cross-sectional diagram of a connection section of a flip chip module;

FIG. 5 is a schematic cross-sectional diagram of a connection section of a flip chip module;

FIG. 6 is a schematic cross-sectional diagram of a connection section of a flip chip module; and

FIG. 7 is a schematic cross-sectional diagram of a connection section of a flip chip module.

### DETAILED DESCRIPTION OF EMBODIMENTS

The embodiments of the invention and the various features and advantageous details thereof are explained more fully with reference to the non-limiting embodiments that are illustrated in the accompanying drawings and detailed in the following description. It should be noted that the features illustrated in the drawings are not necessarily drawn to scale. Descriptions of well-known components and processing techniques are omitted so as to not unnecessarily obscure the embodiments of the invention. The examples used herein are intended merely to facilitate an understanding of ways in which the embodiments of the invention may be practiced and to further enable those of skill in the art to practice the embodiments of the invention. Accordingly, the examples should not be construed as limiting the scope of the embodiments of the invention.

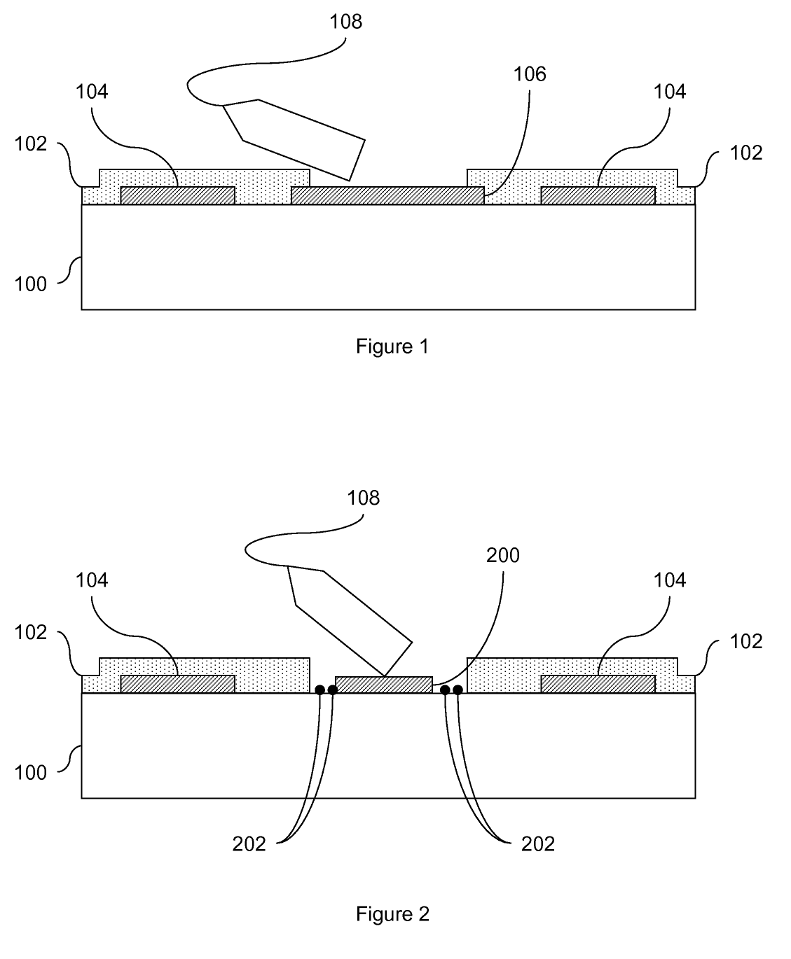

Flip chip laminate substrate electronic component packages that use land grid array terminations for interconnects to the next level of assembly may use two alternative structures to define the interconnect land pad area, as shown in FIGS. 1 and 2. Such structures are not necessarily well-known conventionally. More specifically, in FIGS. 1 and 2 illustrate a flip chip structure that includes an organic substrate 100, at least one wiring conductor 104 on the substrate 100, at least one land grid array (LGA) contact pad 106 on the substrate 100, a solder mask 102 over the wiring conductor 104, and a land grid array structure 108 on the LGA contact pad 106.

These structures are referred to herein as a solder mask defined pad (FIG. 1) and non-solder mask defined pad (FIG. 2). Where solder mask defined pads are used (structures where the solder mask is used to pattern the contact pads) the contact pad 106 must be larger than is actually needed for the contact area alone. This extra size of the contact pad 106 is needed to provide sufficient overlap for the solder mask 102. In addition, because the LGA connector termination (land grid array structure 108) approaches the copper pad 106 at a steep angle, and the solder mask 102 rises above the copper pad 106 by as much as 25 um, the land grid array structure 108 can actually be lifted off the contact pad 106 and, therefore, the copper pad 106 must be significantly larger than required by dimensional tolerance needs to assure that the LGA connector termination 108 does not connect to the corner of the solder mask 102, rather than the Au Ni plated pad 106. This larger pad 106 adds electrical inductance to the path of a signal through the LGA connection, which prevents the use of signals at high speeds (e.g., above about 8 gigahertz.).

Where, as shown in FIG. 2, smaller non solder mask 102 defined pads 200 that have an electroless nickel immersion gold (ENIG) pad finish are used, palladium seed plating residue 202 may remain on the substrate surface prior to plating. In ENIG pad plating, this seed metal residue is also plated with NiAu, forming a larger conductive deposit. This deposit may join the copper pad 200, forming an effectively larger termination, adding inductance to the circuit path. This residue 202 also may form a near short circuit to adjacent conductors 104, posing a reliability risk of the solder mask 102.

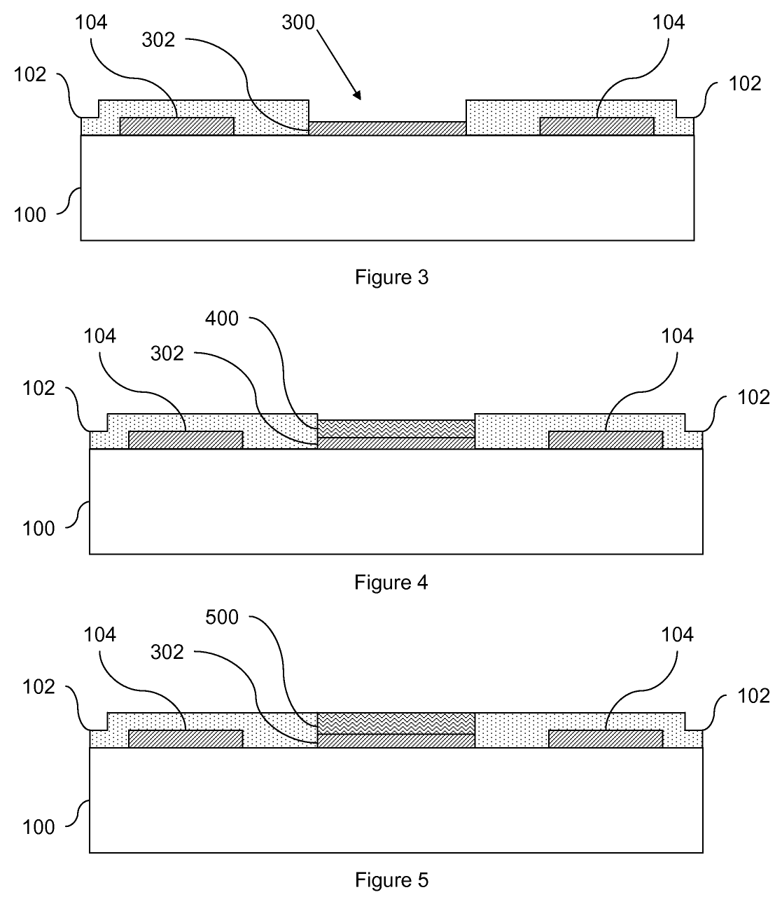

In order to address such issues, the solder mask defined pad dimensions are reduced, as shown in item 302 in FIG. 3, to increase electrical performance. With the embodiments shown in FIGS. 3-7, the solder mask 102 contact opening is filled with electroless plated nickel 400, 500 near its top surface.

More specifically, as shown in FIGS. 3-7 (with the final structure being shown in FIG. 7), one embodiment herein comprises a flip chip structure that includes an organic substrate 100, at least one wiring conductor 104 on the substrate 100, at least one land grid array (LGA) contact pad 302 on the substrate 100, a solder mask 102 over the wiring conductor 104, a contact pad plating layer 400, 500 on the LGA contact pad 302, and a land grid array structure 108 on the LGA contact pad plating layer 400, 500.

The LGA contact pad 302 comprises any conductor, such as copper plated with nickel and gold. All conductors mentioned herein can comprise any conductor including metals, alloys, polysilicon, doped silicon, etc. The wiring conductor 104 comprises a copper wiring conductor 104. The LGA contact pad 302 can sometimes extend a different distance above the substrate 100 than the wiring conductor 104 extends above the substrate 100. The contact pad plating layer 400, 500 comprises any conductor such as electroless nickel immersion gold (ENIG) material.

The solder mask 102 comprises an opening 300 (FIG. 3) over the LGA contact pad 302. The solder mask 102 comprises a bottom surface contacting the contact pad 302 and a top surface opposite the bottom surface. The contact pad plating layer 400, 500 is positioned within the opening 300 of the solder mask 102 and the contact pad plating layer 400, 500 comprises a bottom surface contacting the substrate 100 and a top surface opposite the bottom surface. One feature of embodiments herein is that the top surface of the contact pad plating layer 400, 500 is coplanar (or approximately coplanar) with the top surface of the mask 102. It will be recognized to those with ordinary skill in the art that the use of the term coplanar describes the plane of the top surface of the pad 400, 500 being aligned with the plane of the top surface of the soldermask 102 with a reasonable allowance for tolerance and variation. Thus any increase in plating of the pad 400, 500 or reduction of the soldermask 102 to bring these planes into better alignment without having them in perfect alignment is within the intended scope of the appended claims.

FIG. 3-7 also illustrate one exemplary method embodiment that, as shown beginning in FIG. 3, patterns at least one conductor 104 on a substrate 100, such an organic substrate. The method similarly patterns at least one contact pad 302 on the substrate 100, such as a copper contact pad plated with nickel and gold. This process is performed such that the contact pad 302 can sometimes extend a different distance above the substrate 100 than the conductor 104 extends above the substrate 100.

The structures shown in FIG. 3-7 can be formed using any methods and materials that are now conventionally known or are developed in the future. For example, U.S. Pat. No. 6,708,871 (the complete disclosure of which is incorporated herein by reference) discloses that a board (e.g., an organic substrate of epoxy impregnated fiberglass (FR4) or polyimide, polytetrafluoroethylene (PTFE) or other organic material which will withstand the heat of a liquid solder and the curing temperature of a solder mask material) can include conductive wiring circuits and contact pads. Such conductors can be formed in any conventional manner, such as lithography, additive plating, subtractive processes, etc. The circuitized substrate can be heated (e.g., 125° C.) to thoroughly dry it of any water residue prior to patterning the solder mask 102.

The method patterns the mask 102 over the conductor 104 such that the mask 102 comprises an opening 300 over the contact pad 302 and such that the mask 102 comprises a bottom surface contacting the substrate 100 and a top surface opposite the bottom surface. Such structures can be formed using methods and materials that are well-known to those ordinarily skilled in the art and are not discussed in detail herein. For example, U.S. Pat. Nos. 7,298,623; 6,708,871; and 6,650,016 (the complete disclosures of which are incorporated herein by reference) disclose different methods and materials used in the formation of such a permanent solder mask 102 (e.g., epoxy, acrylate, etc.) laminated to the top surface of the substrate 100.

Thus, for example, after being degassed by applying a vacuum, the solder mask material is applied to the substrate 100 in a liquid or paste form. The solder mask can be smoothed by pressing a flat PTFE (polytetrafluoroethylene) coated glass plate to form a straight, even, uniform, level surface and then laser ablated to form the openings 300, shown in FIG. 3. The contact pad 302 is then formed using any conventional deposition process, including sputtering, deposition, immersion, etc.

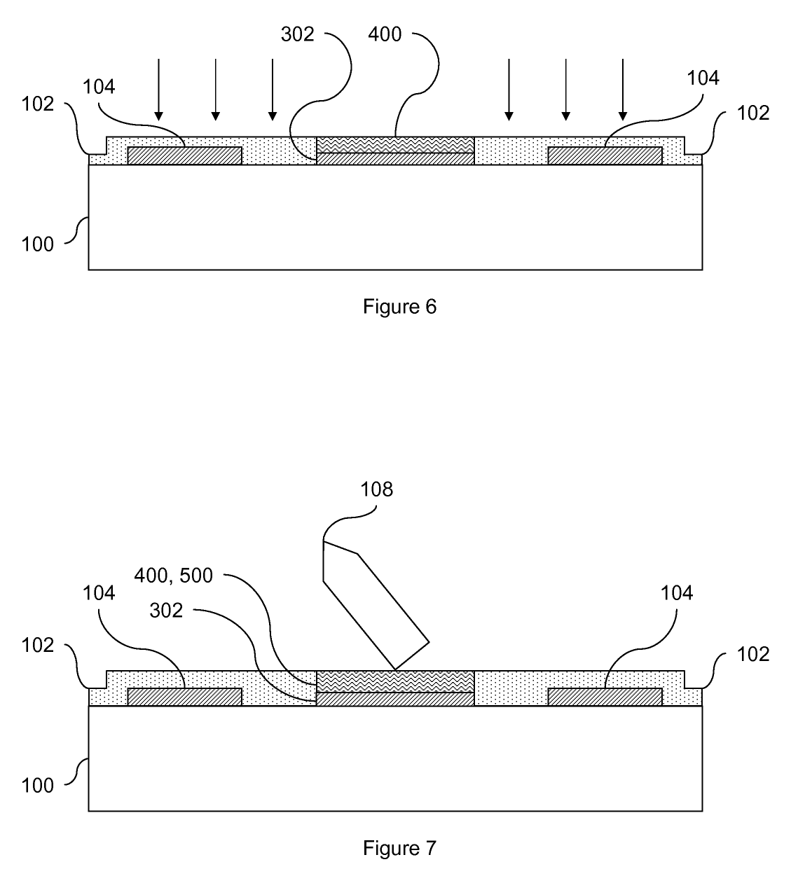

Next, as shown in FIG. 4, the method plates the contact pad and the plating layer is shown in FIG. 4 as item 400 and in FIGS. 5 and 6 as item 500. Such plating structures can be formed using methods and materials that are well-known to those ordinarily skilled in the art and are not discussed in detail herein. For example, U.S. Pat. Nos. 7,328,506; 7,115,997; and 6,436,803 (the complete disclosures of which are incorporated herein by reference) disclose different methods and materials used in electroplating and electroless plating processes.

To make the top of the contact pad plating layer coplanar with the top of the solder mask 102, the contact pad plating layer 400 can be increased in size to become a thicker contact pad plating layer 500 (FIG. 5) by increasing the amount of plating performed on the pad 302 (e.g., additional plating with a different material or longer plating with the same material); or the height of the solder mask 102 can be reduced (FIG. 6) to the existing height of the contact pad plating layer 400, or a combination of the two processes can be used (additional plating combined with reducing the height of the solder mask). Therefore, the contact pad plating layer and/or solder mask can be altered to ensure that the contact pad plating layer has a height equal to the height of the solder pad.

More specifically, with embodiments herein, the exposure to the electroless nickel plating bath (used in the pad plating) can be increased, and/or the solder mask 102 thickness can be reduced. In alternative embodiments, the solder mask 102 thickness can remain the same, while the height of the contact pad plating layer 400 is extended to become item 500. Another alternative is to reduce solder mask 102 thickness to that of the current plating height 400, without increasing the height of the plating to item 500. In additional alternative embodiments, electroless copper or other metal plating can be introduced prior to the electroless nickel bath to increase the height of the contact pad plating layer 400.

As mentioned above, the contact pad plating layer 400, 500 can comprise a conductor (such as an electroless nickel immersion gold (ENIG) or electroless copper or other metal plating material) formed on the contact pad 302 and within the opening 300 of the mask 102. The formation of conductors within openings on laminated flip chips is well known and a detailed discussion of the same is omitted here from. For example, see U.S. Pat. No. 7,309,647 (the complete disclosure of which is incorporated herein by reference) which discusses a method of mounting an electroless nickel immersion gold flip chip package. With all embodiments herein the top surface of the contact pad plating layer 400, 500 is coplanar with the top surface of the mask 102.

Therefore, in the process shown in FIG. 5, the method increases the thickness (height) of the contact pad plating layer 400 to that shown as item 500 so that the contact pad plating layer 500 has a height above the substrate 100 (top of the contact pad plating layer 400) that is equal to the height of the solder mask 102. To the contrary, the process shown in FIG. 6, the contact pad plating layer 500 is not formed to the full height of the solder mask 102 (the top of the contact pad plating layer 400 is below the top of the solder mask 102). Therefore, as shown in FIG. 6, the solder mask 102 is subjected to a material removal process (etching, chemical mechanical planarization (CMP), etc.) until the height of the solder mask 102 is reduced so that it is equal to height of the contact pad plating layer 400.

After these processing steps are completed, column shaped connectors that approach the contact pad plating layer 400, 500 at an angle (other similar land grid array structures 180) are formed on the contact pad plating layer 400, 500. The processes and material used for the formation of such land grid array structures 180 is well known and a detailed discussion of the same is omitted here from. For example, see U.S. Pat. Nos. 7,331,796; 7,302,757; and 7,173,193 (the complete disclosures of which are incorporated herein by reference).

Thus, with LGA applications of embodiments herein, the pad structure metal (contact pad plating layer 400, 500) is flush with the insulator (solder mask) in the height axis. This allows minimized pad design rules to be utilized, enabling better electrical performance than other mask defined pad structures.

The foregoing description of the specific embodiments will so fully reveal the general nature of the invention that others can, by applying current knowledge, readily modify and/or adapt for various applications such specific embodiments without departing from the generic concept, and, therefore, such adaptations and modifications should and are intended to be comprehended within the meaning and range of equivalents of the disclosed embodiments. It is to be understood that the phraseology or terminology employed herein is for the purpose of description and not of limitation. Therefore, while the embodiments of the invention have been described in terms of preferred embodiments, those skilled in the art will recognize that the embodiments of the invention can be practiced with modification within the spirit and scope of the appended claims.

What is claimed is:

1. A structure comprising:
a substrate;
at least one conductor on said substrate;
at least one contact pad on said substrate;
a mask over said conductor, wherein said mask comprises an opening over said contact pad, and wherein said mask comprises a bottom surface contacting said substrate and a top surface opposite set bottom surface; and
a contact pad plating layer on said contact pad and within said opening of said mask,
wherein said contact pad plating layer comprises a bottom surface contacting said substrate and a top surface opposite said bottom surface, and
wherein said top surface of said contact pad plating layer is approximately coplanar with said top surface of said mask.

2. The structure according to claim 1, wherein said contact pad plating layer comprises a conductor.

3. The structure according to claim 1, wherein said contact pad plating layer comprises an electroless nickel immersion gold (ENIG) material.

4. The structure according to claim 1, wherein said contact pad comprises copper plated with nickel and gold.

5. The structure according to claim 1, wherein said conductor comprises a copper conductor.

6. The structure according to claim 1, wherein said contact pad extends a different distance above said substrate than said conductor extends above said substrate.

7. The structure according to claim 1, further comprising a land grid array structure on said contact pad plating layer.

8. A flip chip structure comprising:
a laminated organic substrate;
at least one wiring conductor on said substrate;
at least one land grid array (LGA) contact pad on said substrate;
a solder mask over said wiring conductor, wherein said solder mask comprises an opening over said LGA contact pad, and wherein said solder mask comprises a bottom surface contacting said substrate and a top surface opposite said bottom surface; and
a contact pad plating layer on said LGA contact pad and within said opening of said solder mask,
wherein said contact pad plating layer comprises a bottom surface contacting said substrate and a top surface opposite said bottom surface, and
wherein said top surface of said contact pad plating layer is approximately coplanar with said top surface of said mask.

9. The structure according to claim 8, wherein said contact pad plating layer comprises a conductor.

10. The structure according to claim 8, wherein said contact pad plating layer comprises an electroless nickel immersion gold (ENIG) material.

11. The structure according to claim 8, wherein said LGA contact pad comprises copper plated with nickel and gold.

12. The structure according to claim 8, wherein said wiring conductors comprise copper wiring conductors.

13. The structure according to claim 8, wherein said LGA contact pad extends a different distance above said substrate than said wiring conductors extend above said substrate.

14. The structure according to claim 8, further comprising a land grid array structure on said LGA contact pad plating layer.

15. A method comprising:
patterning at least one conductor on a substrate;
patterning at least one contact pad on said substrate;
patterning a mask over said conductors such that said mask comprises an opening over said contact pad and such that said mask comprises a bottom surface contacting said substrate and a top surface opposite said bottom surface; and
forming a contact pad plating layer on said contact pad and within said opening of said mask, such that said contact pad plating layer comprises a bottom surface contacting said substrate and a top surface opposite said bottom surface, and such that said top surface of said contact pad plating layer is approximately coplanar with said top surface of said mask.

16. The method according to claim 15, further comprising reducing a thickness of said mask until said top of said mask is coplanar with said top of said contact pad plaiting layer.

17. The method according to claim 15, wherein said forming of said contact pad plating layer comprises forming a conductive contact pad plating layer.

18. The method according to claim 15, wherein said forming of said contact pad plating layer comprises forming an electroless nickel immersion gold (ENIG) material contact pad plating layer.

19. The method according to claim 15, wherein said forming of said contact pad comprises forming a copper contact pad plated with nickel and gold contact pad.

20. The method according to claim 15, further comprising forming a land grid array structure on said contact pad plating layer.
